(19) United States
(12) Patent Application Publication
(10) Pub. No.: US 2024/0192506 A1
(43) Pub. Date: Jun. 13, 2024

(54) Device With Molded Polymer Structures

(71) Applicant: Apple Inc., Cupertino, CA (US)

(72) Inventors: Christopher Patton, San Jose, CA (US); Michael J. Oudenhoven, San Francisco, CA (US); Suresh C. Gopalan, San Jose, CA (US)

(21) Appl. No.: 18/444,114

(22) Filed: Feb. 16, 2024

Related U.S. Application Data
(63) Continuation of application No. PCT/US22/43367, filed on Sep. 13, 2022.
(60) Provisional application No. 63/246,409, filed on Sep. 21, 2021.

(51) Int. Cl. G02B 27/01

(52) U.S. Cl. CPC G02B 27/0176; G02B 2027/0178

(57) ABSTRACT

A head-mounted device may have a head-mounted frame with lens openings. The head-mounted device may have left and right lenses mounted in the lens openings. The lenses may include waveguides that help guide images from projectors to eye boxes for viewing by a user. The frame may include a metal frame member that supplies the frame with structural support. Circuitry such as strain gauge circuitry and cabling may be coupled to the metal frame member. A protective polymer such as thermoset epoxy may be used to encapsulate and protect the circuitry. The protective polymer may encapsulate the strain gauge, the cabling, and/or other circuitry so that this circuitry need not be exposed to elevated temperatures during subsequent injection molding operations. Injection molding may be used to apply one or more shots of thermoplastic polymer to the metal frame member to form the head-mounted frame.

This application is a continuation of international patent application No. PCT/US2022/043367, filed Sep. 13, 2022, which claims priority to U.S. provisional patent application No. 63/246,409, filed Sep. 21, 2021, which are hereby incorporated by reference herein in their entireties.

### FIELD

This relates generally to electronic devices, and, more particularly, to electronic devices such as head-mounted devices.

### BACKGROUND

Electronic devices such as head-mounted devices may have displays for displaying images. The displays may be housed in a head-mounted support structure.

### SUMMARY

A head-mounted device may have a head-mounted frame with lens openings. The head-mounted device may have left and right lenses mounted in the lens openings. The lenses may include waveguides that help guide images from projectors to eye boxes for viewing by a user.

The head-mounted frame may include an internal frame member that provides the frame with structural support. The frame member may, for example, be a metal frame member. The metal frame member, which may sometimes be referred to as a metal frame structure or metal frame, may have mounting structures such as tabs to which the projectors are attached.

Circuitry such as strain gauge circuitry and cabling may be coupled to the metal frame member. A protective polymer such as thermoset epoxy may be used to encapsulate and protect the circuitry. The protective polymer may encapsulate the strain gauge, the cabling, and/or other circuitry so that this circuitry need not be exposed to elevated temperatures during subsequent injection molding operations. After the protective polymer structures have been formed, injection molding may be used to apply one or more shots of thermoplastic polymer to the metal frame member and the projective polymer on the frame member to form the head-mounted frame.

### BRIEF DESCRIPTION OF THE DRAWINGS

FIG. 1 is a schematic diagram of an illustrative electronic device such as a head-mounted display device in accordance with an embodiment.

FIG. 2 is a top view of an illustrative head-mounted device in accordance with an embodiment.

FIG. 3 is a rear perspective view of the underside of a head-mounted device in accordance with an embodiment.

FIG. 4 is a perspective view of an illustrative frame member and associated circuitry for a head-mounted device in accordance with an embodiment.

FIG. 5 is a front view of the illustrative components of FIG. 4 after a protective polymer structure has been formed over part of the frame member and other components in accordance with an embodiment.

FIG. 6 is a perspective view of a portion of an illustrative head-mounted device frame after a first (rear) shot of polymer has been formed on the structures of FIG. 5 in accordance with an embodiment.

FIG. 7 is a cross-sectional side view of a portion of the illustrative frame after a second (front) shot of polymer has been formed on the structures of FIG. 6 in accordance with an embodiment.

FIG. 8 is a cross-sectional side view of an upper portion of a head-mounted device frame following application of the first and second shots of polymer in accordance with an embodiment.

FIG. 9 is a perspective view of an illustrative frame for a head-mounted device in accordance with an embodiment.

FIG. 10 is a flow chart of illustrative operations involved in forming a head-mounted device of the type shown in FIG. 9 in accordance with an embodiment.

### DETAILED DESCRIPTION

Electronic devices such as head-mounted devices may include displays and other components for presenting content to users. A head-mounted device may have head-mounted support structures that allow the head-mounted device to be worn on a user's head. The head-mounted support structures may support optical components such as displays for displaying visual content and front-facing cameras for capturing real-world images. In an illustrative configuration, optical components such as waveguides may be used to provide images from display projectors to eye boxes for viewing by a user.

The head-mounted device may have sensors. For example, a strain gauge sensor may be used to monitor for potential deformation of the support structures (e.g., twisting, bending, etc.). Deformation of the support structures (e.g., deformation of a glasses frame member or other head-mounted support structure due to excessive force such as force from a drop event) may potentially lead to optical component misalignment and image distortion. By monitoring for frame bending and other support structure deformations using strain gauge sensor circuitry, corrective actions may be taken to prevent undesired image distortion. For example, digital image warping operations may be performed on digital image data being provided to the projectors and/or other actions may be taken to compensate for the deformation. In this way, the head-mounted device may compensate for the measured support structure deformation.

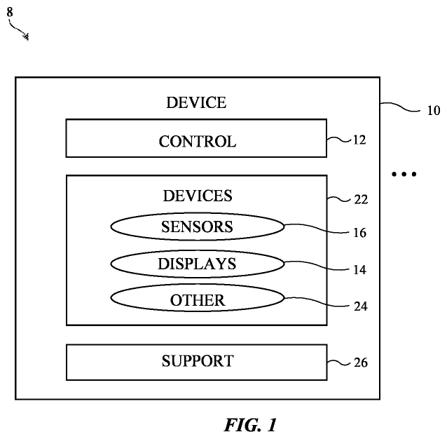

A schematic diagram of an illustrative system that may include a head-mounted device is shown in FIG. 1. As shown in FIG. 1, system 8 may include one or more electronic devices such as electronic device 10. The electronic devices of system 8 may include computers, cellular telephones, head-mounted devices, wristwatch devices, and other electronic devices. Configurations in which electronic device 10 is a head-mounted device are sometimes described herein as an example.

As shown in FIG. 1, electronic devices such as electronic device 10 may have control circuitry 12. Control circuitry 12 may include storage and processing circuitry for controlling the operation of device 10. Circuitry 12 may include storage such as hard disk drive storage, nonvolatile memory (e.g., electrically-programmable-read-only memory configured to form a solid-state drive), volatile memory (e.g., static or dynamic random-access-memory), etc. Processing circuitry in control circuitry 12 may be based on one or more microprocessors, microcontrollers, digital signal processors, baseband processors, power management units, audio chips, graphics processing units, application specific integrated circuits, and other integrated circuits. Software code may be stored on storage in circuitry 12 and run on processing circuitry in circuitry 12 to implement control operations for device 10 (e.g., data gathering operations, operations involving the adjustment of the components of device 10 using control signals, etc.). Control circuitry 12 may include wired and wireless communications circuitry. For example, control circuitry 12 may include radio-frequency transceiver circuitry such as cellular telephone transceiver circuitry, wireless local area network transceiver circuitry (e.g., WiFi® circuitry), millimeter wave transceiver circuitry, and/or other wireless communications circuitry.

During operation, the communications circuitry of the devices in system 8 (e.g., the communications circuitry of control circuitry 12 of device 10), may be used to support communication between the electronic devices. For example, one electronic device may transmit video data, audio data, and/or other data to another electronic device in system 8. Electronic devices in system 8 may use wired and/or wireless communications circuitry to communicate through one or more communications networks (e.g., the internet, local area networks, etc.). The communications circuitry may be used to allow data to be received by device 10 from external equipment (e.g., a tethered computer, a portable device such as a handheld device or laptop computer, online computing equipment such as a remote server or other remote computing equipment, or other electrical equipment) and/or to provide data to external equipment.

Device 10 may include input-output devices 22. Input-output devices 22 may be used to allow a user to provide device 10 with user input. Input-output devices 22 may also be used to gather information on the environment in which device 10 is operating. Output components in devices 22 may allow device 10 to provide a user with output and may be used to communicate with external electrical equipment.

As shown in FIG. 1, input-output devices 22 may include one or more displays such as displays 14. In some configurations, device 10 includes left and right display devices (e.g., left and right components such as left and right projectors based on scanning mirror display devices, liquid-crystal-on-silicon display devices, digital mirror devices, or other reflective display devices, left and right display panels based on light-emitting diode pixel arrays (e.g., organic light-emitting display panels or display devices based on pixel arrays formed from crystalline semiconductor light-emitting diode dies), liquid crystal display panels, and/or or other left and right display devices that provide images to left and right eye boxes for viewing by the user's left and right eyes, respectively. Illustrative configurations in which device 10 has left and right display devices such as left and right projectors that provide respective left and right images for a user's left and right eyes may sometimes be described herein as an example.

Displays 14 are used to display visual content for a user of device 10. The content that is presented on displays 14 may include virtual objects and other content that is provided to displays 14 by control circuitry 12. This virtual content may sometimes be referred to as computer-generated content. Computer-generated content may be displayed in the absence of real-world content or may be combined with real-world content. For example, an optical coupling system may be used to allow computer-generated content to be optically overlaid on top of a real-world image. In particular, device 10 may have a see-through display system that provides a computer-generated image to a user through a beam splitter, prism, holographic coupler, diffraction grating, or other optical coupler (e.g., an output coupler on a waveguide that is being used to provide computer-generated images to the user) while allowing the user to view real-world objects through the optical coupler and other transparent structures (e.g., transparent waveguide structures, vision-correction lenses and/or other lenses, etc.).

Input-output circuitry 22 may include sensors 16. Sensors 16 may include, for example, three-dimensional sensors (e.g., three-dimensional image sensors such as structured light sensors that emit beams of light and that use two-dimensional digital image sensors to gather image data for three-dimensional images from light spots that are produced when a target is illuminated by the beams of light, binocular three-dimensional image sensors that gather three-dimensional images using two or more cameras in a binocular imaging arrangement, three-dimensional lidar (light detection and ranging) sensors, three-dimensional radio-frequency sensors, or other sensors that gather three-dimensional image data), cameras (e.g., infrared and/or visible digital image sensors), gaze tracking sensors (e.g., a gaze tracking system based on an image sensor and, if desired, a light source that emits one or more beams of light that are tracked using the image sensor after reflecting from a user's eyes), touch sensors, capacitive proximity sensors, light-based (optical) proximity sensors, other proximity sensors, force sensors, sensors such as contact sensors based on switches, gas sensors, pressure sensors, moisture sensors, magnetic sensors, audio sensors (microphones), ambient light sensors, microphones for gathering voice commands and other audio input, sensors that are configured to gather information on motion, position, and/or orientation (e.g., accelerometers, gyroscopes, compasses, and/or inertial measurement units that include all of these sensors or a subset of one or two of these sensors), strain gauge sensors, and/or other sensors.

User input and other information may be gathered using sensors and other input devices in input-output devices 22. If desired, input-output devices 22 may include other devices 24 such as haptic output devices (e.g., vibrating components), light-emitting diodes and other light sources, speakers such as ear speakers for producing audio output, circuits for receiving wireless power, circuits for transmitting power wirelessly to other devices, batteries and other energy storage devices (e.g., capacitors), joysticks, buttons, and/or other components.

Electronic device 10 may have housing structures as shown by illustrative support structures 26 of FIG. 1. In configurations in which electronic device 10 is a head-mounted device (e.g., a pair of glasses, goggles, a helmet, a hat, etc.), support structures 26 may include head-mounted support structures (e.g., a helmet housing, head straps, arms or temples in a pair of eyeglasses, goggle housing structures, and/or other head-mounted structures). A head-mounted support structure may be configured to be worn on a head of a user during operation of device 10 and may support displays 14, sensors 16, other components 24, other input-output devices 22, and control circuitry 12.

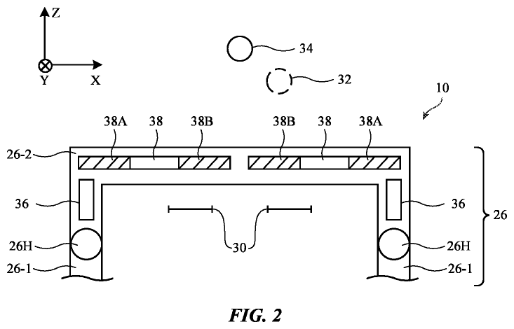

FIG. 2 is a top view of electronic device 10 in an illustrative configuration in which electronic device 10 is a head-mounted device. As shown in FIG. 2, electronic device 10 may include head-mounted support structure 26 to house the components of device 10 and to support device 10 on a user's head. Support structure 26 may include, for example, structures that form housing walls and other structures at the front of device 10 (sometimes referred to as a frame, lens support frame, glasses frame, etc.). In particular, support structure 26 may include support structures 26-2 at the front of device 10, which form glasses frame structures such as a nose bridge, a frame portion that supports left and right lenses with embedded waveguides, and/or other housing structures. Support structure 26 may also include additional structures such as straps, glasses arms, or other supplemental support structures (e.g., support structures 26-1) that help to hold the frame and the components in the frame on a user's face so that the user's eyes are located within eye boxes 30. If desired, support structure 26 may include hinges such as hinges 26H. Support structures 26-1 (which may sometimes be referred to as arms or temples) may be coupled to support structures 26-2 (which may sometimes be referred to as a glasses frame, lens frame, or frame) using hinges 26H (e.g., so that the arms of device 10 can be folded parallel to the frame at the front of device 10 when not in use).

During operation of device 10, images are presented to a user's eyes in eye boxes 30. Eye boxes 30 include a left eye box that receives a left image and a right eye box that receives a right image. Device 10 may include a left display system with a left display 14 that presents the left image to the left eye box and a right display system with a right display 14 that presents the right image to the right eye box. In an illustrative configuration, each display system may have an optical combiner assembly that helps combine display images (e.g., computer-generated image 32 of FIG. 2, sometimes referred to as a virtual image) with real-world image light (e.g., light from real-world objects such as object 34 of FIG. 2). Optical combiner assemblies may include optical couplers, waveguides, and/or other components.

As an example, each display system may have a corresponding projector 36, a waveguide 38, and an optical coupler (e.g., a prism and/or other optical coupling element(s)) to couple an image from the projector into the waveguide from the projector. An output coupler on each waveguide may be used to couple the image out of that waveguide towards a respective eye box after the waveguide has guided the image to a location overlapping the eye box.

In the illustrative configuration of FIG. 2, a left projector 36 may produce a left image and a right projector 36 may produce a right image. Left and right waveguides 38 at the front of device 10 may be provided with left and right optical input couplers 38A that respectively receive the left and right images and couple those images into the left and right waveguides. Waveguides 38 then convey the received images laterally towards the center of device 10 in accordance with the principal of total internal reflection. The left and right images (e.g., computer-generated image 32) are coupled out of the waveguides towards eye boxes 30 using output couplers 38B (e.g., gratings, holographic output couplers, or other suitable output couplers). Output couplers 38B are transparent so that a user may view real-world objects such as object 34 from eye boxes 30.

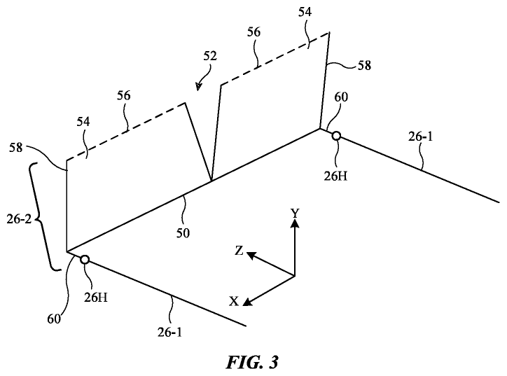

FIG. 3 is a simplified rear perspective view of head-mounted device 10 taken from the underside of device 10. As shown in FIG. 3, support structures 26-1 may be configured to form left and right glasses arms (sometimes referred to as temples or frame supports). The arms of device 10 may be coupled to hinges 26H. When device 10 is being worn on a user's head, the left and right arms of device 10 may extend respectively along the left and right sides of the user's head. Structures 26-2 may include front frame portions such as top frame portion 50 (sometimes referred to as a top frame member, a top frame structure, a top frame portion, or an upper frame edge support structure), which extends from left to right laterally across the top of device 10 when device 10 is being worn by a user. Structures 26-2 may also include left and right side frame portions 58 (sometimes referred to as frame edge members or edge support structures) that extend downwards from top frame portion 50 when device 10 is being worn by a user. In the center of device 10, support structures 26-2 may form nose bridge portion 52 (e.g., the glasses frame formed by structures 26-2 may include nose bridge structures that extends downward from top frame member 50 (e.g., a top frame structure, top frame portion, etc.) on the left and right sides of the user's nose when device 10 is being worn on the head of a user). Portions 60 of structures 26-2, which may sometimes be referred to as glasses frame rearward extensions, side housing extensions, end pieces, or temples, may extend rearwardly to hinges 26H from the glasses frame at the front of device 10 that is formed by portion 50, nose bridge portion 52, and side frame portions 58.

Support structures 26-2 may be configured to support left and right glasses lenses 54. Optional lower frame portions 56 may run along the lower edge of each lens 54 to help support the bottom of lenses 54. Lenses 54 may contain embedded waveguides for laterally transporting images from display projectors to locations that overlap eye boxes 30 (FIG. 2), may contain outer and inner optical elements such as protective transparent layers, vision correction lenses, fixed and/or tunable lenses that help establish a desired virtual image distance for virtual image 32, and/or other optical structures (e.g., light modulator layers, polarizer structures, etc.). In an illustrative configuration, device 10 has a left glasses lens with a left waveguide and output coupler (and, if desired, additional structures such as one or more lens elements with associated optical powers) and a right glasses lens with a right waveguide and right output coupler (and, if desired, additional structures such as one or more lens elements with associated non-zero optical powers). The left waveguide and right waveguide may, as an example, each be sandwiched between outer and inner transparent optical structures (e.g., lens elements, protective transparent layers, etc.). During operation, projectors 36 (FIG. 2) may provide left and right images to the left and right waveguides, respectively. The left and right waveguides may respectively guide the left and right images to portions of lenses 54 with output couplers that overlap eye boxes 30, where the output couplers may direct the left and right images to corresponding left and right eye boxes for viewing by the user's left and right eyes.

During use of device 10, device 10 may be subjected to undesirably larger forces (e.g., during drop events). These excessive forces may cause structures 26 to bend or otherwise deform, which could lead to misalignment between the optical components of device 10. Consider, for example, a scenario in which nose bridge portion 52 of structures 26-2 bends about the Y axis of FIG. 3. In this scenario, the left and right images provided to the left and right eye boxes will diverge (or converge) and will not be satisfactorily aligned with eye boxes 30. As another example, consider a scenario in which nose bridge portion 52 is twisted about the X axis. In this scenario, the left image will be provided above its desired position in the left eye box and the right image will be provided below its desired position in the right eye box (as an example). Deformation of structures 26 may also cause the waveguides in device 10 to become misaligned relative to the projectors in device 10. As these illustrative scenarios demonstrate, deformations of structures 26 due to undesired excessive forces may lead to misalignment and potentials for image distortion (image shifting, keystoning, etc.). These image distortion effects can be compensated for digitally by applying compensating image warping to the image data being supplied to the left and right projectors.

Sensor measurements (e.g., using sensors 16) may be used in measuring deformations to structures 26 and/or other sources of optical system misalignment, so that control circuitry 12 can take corrective action. As an example, frame deformations may be measured using strain gauge circuitry mounted in nose bridge portion 52 and/or other areas of the frame. The strain gauge circuitry may include one or more strain gauges (e.g., one or more sets of strain gauge sensor electrodes that exhibit measurable changes in resistance when bent). The strain gauge circuitry may measure support structure deformation (e.g., frame twisting, frame bending, etc.). In an illustrative scenario, which may sometimes be described herein as an example, the frame of device 10 may have an internal support member such as a metal frame member (e.g., a metal frame structure, metal frame, metal frame portion, etc.) to which a strain gauge is attached. Bending and/or twisting may be measured about any suitable dimensions (e.g., about axis X, axis Y, and/or axis Z).

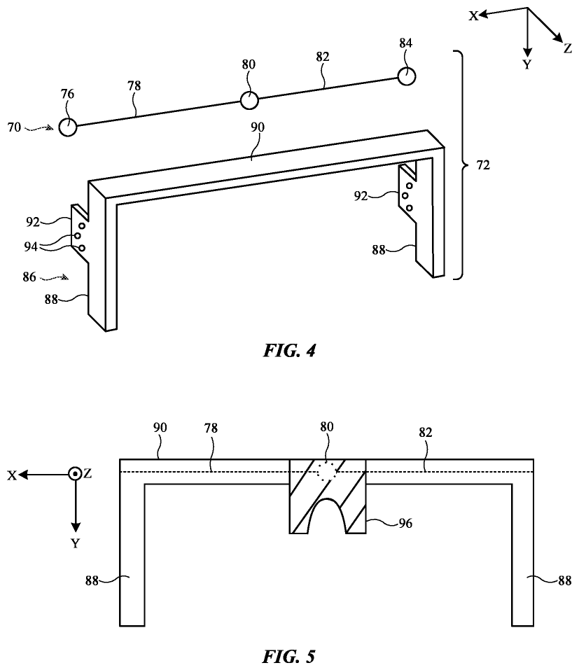

FIG. 4 is a perspective view of illustrative components 72 for forming an interior portion of device 10. Components 72 may include an internal frame member such as frame member 86 (e.g., an internal frame, internal frame structure, internal frame portion, etc.) and associated circuitry 70 that may be attached to frame member 86 during frame assembly operations. Frame member 86 may have a C-shape or other suitable shape. In the illustrative configuration of FIG. 4, frame member 86 has an upper portion 90 (e.g., an elongated bar that extends across the width of the frame of device 10) and has side portions 88 that extend downwardly from upper portion 90.

Circuitry 70 may include circuits 76, 80, and 84 coupled using signal paths 78 and 82. Circuit 80 may include strain gauge circuitry (e.g., a strain gauge formed on a flexible printed circuit). The strain gauge may be coupled to a central region of upper portion 90 of frame member 86 to monitor for deformation of the frame member. Circuits 76 and 84 may include integrated circuits and other components for forming control circuitry 12, displays 14 (e.g., projectors 36 of FIG. 2), other input-output devices 22 such as speakers, batteries, etc. Signal paths 78 and 82 (e.g., signal lines formed from wires in cables, metal traces on printed circuits, etc.) may be used in electrically connecting circuits 76, 80, and 84. In this way, power may be routed from batteries in device 10 to integrated circuits, sensors, displays, and other powered components, data from sensors may be routed to control circuitry, control signals and other output may be routed from control circuitry to adjustable components (e.g., displays, actuators, speakers, etc.), etc. The signals carried by paths 78 and 82 may include analog and/or digital signals.

To provide device 10 with desired strength and rigidity, the glasses frame formed from structures 26 may include an outer portion covering one or more inner supporting portions. In particular, structures 26 may include an internal frame member such as frame member 86 of FIG. 4 (sometimes referred to as an inner frame, glasses frame member, internal frame member, stiffening member, etc.).

Frame member 86 may be formed from a rigid material such as metal, carbon-fiber composite material or other fiber composites (e.g., polymer containing embedded stiffening fibers of glass, carbon, or other fiber materials), may include a stiff polymer, glass, ceramic, etc. In an illustrative configuration, which may sometimes be described herein as an example, frame member 86 may be formed from metal (e.g., aluminum, titanium, steel, magnesium, and/or other elemental metals and/or metal alloys) and may sometimes be referred to as a metal frame, metal member, or metal frame member. Metal frame member 86 may be machined (e.g., using a computer numerical control tool or other suitable shaping equipment) and/or may be otherwise shaped into a desired final configuration.

In the example of FIG. 5, frame member 86 has mounting tabs 92 that extend rearwardly from side portion 88. Tabs 92 may have openings 94 to accept screws or other fasteners. This allows tabs 92 to serve as component support structures. As an example, projectors in circuits 76 and 84 may be mounted to tabs 92.

A central region of portion 90 of frame member 86 may, if desired, include one or more planar surfaces. These surfaces may be characterized by respective surface normals. For example, the top surface of portion 90 may have a surface normal oriented along the −Y direction and the side surfaces of portion 90 may have surface normals oriented orthogonally (e.g., along the + and −Z directions, respectively). The strain gauge of circuit 80 may have a flexible printed circuit with strain gauge sensor traces. The flexible printed circuit may have a first portion with first traces attached to the top surface and a second portion with second traces attached to one of the side surfaces of portion 90. In this way, the strain gauge may measure bending of member 86 so that corrective actions may be taken to prevent undesired image distortion.

If desired, portion 90 may have a cable routing recess (e.g., a cable channel) that receives a cable forming paths 78 and 80. The channel may be sealed using a protective polymer layer (sometimes referred to as a protective polymer portion, protective polymer frame portion, protective polymer, etc.). Some of the protective polymer material that is used in sealing the cabling of circuitry 70 into the cable channel may be used to encapsulate and protect circuit 80. As shown in FIG. 5, for example, protective polymer member 96 may be formed over a central area of portion 90 and over circuit 80. Any suitable polymer may be used in protecting circuitry 70. As an illustrative example, the protective polymer may be epoxy (e.g., a thermoset epoxy) or other polymer with a low curing temperature. Epoxy or other thermoset polymers may, if desired, be cured using ultraviolet light (as an example). When curing the protective polymer in this way, circuitry 70 need not be exposed to elevated temperatures.

After using the protective polymer to seal paths 78 and 82 into the cable channels on the underside of portion 90 and to form a protective structure such as member 96 that covers and protects circuit 80, higher-temperature polymer molding operations may be performed. In an illustrative example, first and second shots of a thermoplastic polymer are applied over the structures of FIG. 5 using injection molding (e.g., a second polymer may be molded over the first polymer to form a molded polymer portion of the frame). Other polymer application techniques may be used, if desired.

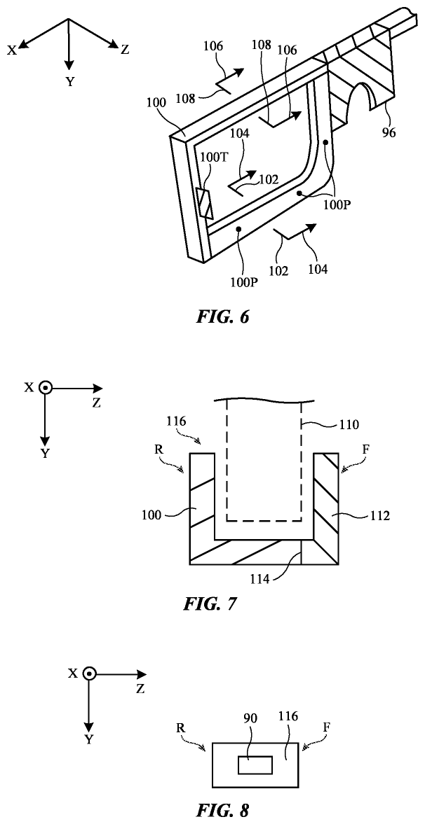

Initially, a first shot of injection-molded polymer (sometimes referred to as a rear frame shot or first molded polymer portion) such as first shot 100 of FIG. 6 is applied. First shot 100 may form a rear portion of the frame of device 10 (e.g., a rear portion of support structure portion 26-2). This portion may include forward-facing tabs or other protrusions such as tab 100T to form engagement surfaces for a subsequent second shot of injection-molded polymer (sometimes referred to as a front frame shot or second molded polymer portion) that forms the front portion of the frame of device 10.

As shown in FIG. 6, first shot 100 may also have a shape that defines optical component mounting structures such as eyeglass lens mounting structures. This shape may include, for example, recesses, one or more ledges such as ledge portion 100L with optional protrusions 100P (e.g., mounting posts to which a lens mounting flexure is attached), and/or other structures to support lens elements, a waveguide, and/or other structures in an eyeglass lens for device 10.

After first shot 100 has been applied, a subsequent second shot of injection-molded polymer may be applied. FIG. 7 is a cross-sectional side view of the frame structures of FIG. 6 following application of an illustrative second shot of polymer. The cross-sectional side view of FIG. 7 is taken along lines 102 of FIG. 6 and is viewed in direction 104. As shown in FIG. 7, frame 116 may include the first (rear) polymer shot (shot 100), which forms a rear frame portion, and may include the second (front) polymer shot (shot 112, which is attached to shot 100 along seam 114), which forms a front frame portion. Shots 100 and 112 may be configured to form a lens-shaped opening on each side of device 10 (e.g., an opening having the shape of the opening in shot 100 of FIG. 6). A channel or other lens mounting recess, a ledge, or other optical component mounting structures may be formed by shots 100 and 112 (which collectively are used in forming frame 116). These optical component mounting structures may be used for mounting inner and outer lens elements, a waveguide between the inner and outer lens elements, and/or other optical components. As shown in FIG. 7, as an example, shots 100 and 112 may form a recess and/or other structures (e.g., a ledge, etc.) to receive the peripheral edge of optical structures 110 (e.g., optical structures such as lens elements, a waveguide, peripheral optical component mounting structures coupled to a peripheral edge of a lens element or waveguide, and/or other structures associated with the each of the eyeglass lenses of device 10). Because the waveguide and other optical components supported in the left and right lens openings of frame 116 serve as eyeglass lenses for device 10, optical structures 110 (e.g., outer and inner lens elements and a waveguide between these elements, etc.) may sometimes be referred to a lenses 110.

FIG. 8 is another cross-sectional side view of the frame structure of FIG. 6 following application of the second shot of polymer to form frame 116. The cross-sectional side view of FIG. 8 is taken along line 108 of FIG. 6 and is viewed in direction 106 following application of second shot 112 to first shot 100 to form frame 116. As shown in FIG. 8, the polymer of frame 116 may surround all (or at least some) of portion 90 of frame member 86. This provides the frame of device 10 with a desired outward appearance.

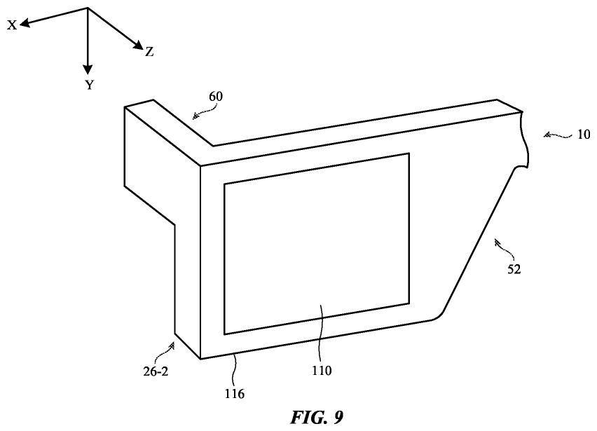

FIG. 9 is a perspective view of device 10 following molding operations. As shown in FIG. 9, portion 26-2 of structures 26 may be formed from injection-molded shots of polymer that form frame 116. Left and right optical structures (eyeglass lenses) 110, which may include waveguides, lens elements, etc., may be mounted in lens openings in frame 116 to the left and right of nose bridge portion 52. Some of frame 116 may be used in forming rearwardly extending portions 60, if desired.

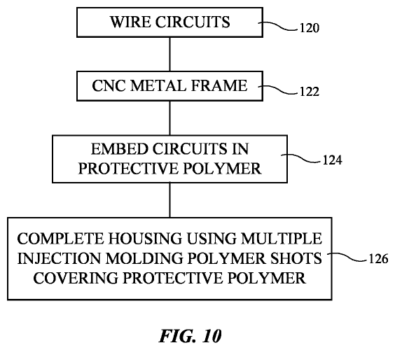

FIG. 10 is a flow chart of illustrative operations involved in forming device 10.

During the operations of block 120, circuitry 70 is formed by soldering and/or otherwise electrically connecting circuits 76, 80, and 84 together using cables such as coaxial cable bundles and/or other signal paths 78 and 82.

During the operations of block 122, frame member 86 may be formed by machining and/or otherwise shaping a block of metal (e.g., using a CNC tool). Frame member 86 may be provided with a downwardly facing C-shape of the type shown in FIG. 4 or other suitable shape. Frame member 86 may, if desired, be provided with planar surfaces and/or other surfaces to which the strain gauge flexible printed circuit of circuit 80 may be attached (e.g., using adhesive), thereby allowing circuit 80 to monitor deformation of frame member 86 during operation of device 10.

After attaching circuitry 70 to frame member 86 (e.g., to route cables associated with paths 78 and 82 in a channel on the underside of portion 90 and to attach the strain gauge flexible printed circuit portion to the planar surfaces at the center of portion 90), protective polymer 96 may be applied. In particular, during the operations of block 124, a protective polymer such as epoxy (e.g., ultraviolet-light cured thermoset epoxy or other polymer that may be applied at relatively low temperatures) may be molded onto components 72. In this way, protective structures such as protective structure 96 may be formed on the frame member that cover and encapsulate sensitive circuitry such as circuit 80 (e.g., the strain gauge traces and associated integrated circuits for the strain gauge such as an amplifier and analog-to-digital converter).

After embedding cables, circuit 80, and/or other circuitry 70 that is potentially sensitive to elevated temperatures in epoxy or other protective polymer during the operations of block 124, frame fabrication may be completed by molding higher temperature polymer onto the frame. In particular, during the operations of block 126, one or more shots of molded polymer such as illustrative shots 100 and 112 of FIG. 7 (e.g., injection molded thermoplastic polymer) may be molded onto the frame structures to form frame 116 of FIG. 9. Assembly of device 10 may then be finished (e.g., lenses 110 may be installed in the completed frame).

In some embodiments, sensors may gather personal user information. To ensure that the privacy of users is preserved, all applicable privacy regulations should be met or exceeded and best practices for handling of personal user information should be followed. Users may be permitted to control the use of their personal information in accordance with their preferences.

In accordance with an embodiment, a head-mounted device is provided that includes an internal frame, a cable attached to the internal frame, protective polymer that covers at least part of the cable, a molded polymer frame portion molded over the protective polymer, the molded polymer frame portion is configured to form lens openings, and lenses in the lens openings.

In accordance with another embodiment, the protective polymer includes epoxy, the molded polymer frame portion includes injection-molded thermoplastic polymer, the lenses include waveguides, and the head-mounted device includes projectors configured to provide images that are guided in the waveguides.

In accordance with another embodiment, the head-mounted device includes a strain gauge that is covered by the protective polymer.

In accordance with another embodiment, the protective polymer includes epoxy.

In accordance with another embodiment, the epoxy includes ultraviolet-light-cured thermoset epoxy and the molded polymer frame portion includes thermoplastic polymer.

In accordance with another embodiment, the thermoplastic polymer includes injection-molded thermoplastic polymer and the molded polymer frame portion is configured to form a nose bridge portion.

In accordance with another embodiment, the head-mounted device includes a strain gauge embedded in the protective polymer.

In accordance with another embodiment, the strain gauge is configured to measure deformation of the internal frame.

In accordance with another embodiment, the internal frame includes a metal internal frame.

In accordance with another embodiment, the metal internal frame has a C-shape.

In accordance with another embodiment, the molded polymer frame portion is molded over at least part of the metal internal frame.

In accordance with another embodiment, the thermoplastic polymer includes a rear shot of thermoplastic polymer and a front shot of thermoplastic polymer.

In accordance with another embodiment, the rear shot of thermoplastic polymer is configured to form a lens ledge.

In accordance with another embodiment, the rear shot of polymer is configured to form lens mounting protrusions.

In accordance with another embodiment, the internal frame includes a metal internal frame with tabs, the head-mounted device includes projectors that are attached to the tabs.

In accordance with another embodiment, the lenses include waveguides that guide images received from the projectors.

In accordance with another embodiment, the cable is coupled to the projectors, the head-mounted device includes a strain gauge coupled to the cable, the strain gauge is configured to measure deformation of the metal internal frame, and the protective polymer encapsulates the strain gauge.

In accordance with an embodiment, a head-mounted device is provided that includes a cable, a sensor, a head-mounted frame including a metal frame that supports the cable and the sensor, thermoset polymer that is formed on at least part of the metal frame and that encapsulates at least part of the cable and the sensor, and thermoplastic polymer that is formed over the thermoset polymer and the metal frame, the thermoplastic polymer is configured to from lens openings, and left and right lenses in the lens openings.

In accordance with another embodiment, the thermoset polymer includes epoxy.

In accordance with an embodiment, a head-mounted device is provided that includes a metal frame, projectors attached to opposing sides of the metal frame, a strain gauge at a central region of the metal frame, cabling coupled to the projectors and the strain gauge, epoxy that covers the strain gauge, thermoplastic polymer covering the epoxy and the metal frame, the thermoplastic polymer is configured to form lens openings, and lenses in the lens openings, the lenses include waveguides configured to guide images from the projectors.

The foregoing is merely illustrative and various modifications can be made to the described embodiments. The foregoing embodiments may be implemented individually or in any combination.

What is claimed is:

1. A head-mounted device, comprising:
an internal frame;
a cable attached to the internal frame;
protective polymer that covers at least part of the cable;
a molded polymer frame portion molded over the protective polymer, wherein the molded polymer frame portion is configured to form lens openings; and
lenses in the lens openings.

2. The head-mounted device defined in claim 1 wherein the protective polymer comprises epoxy, wherein the molded polymer frame portion comprises injection-molded thermoplastic polymer, wherein the lenses comprise waveguides, and wherein the head-mounted device further comprises projectors configured to provide images that are guided in the waveguides.

3. The head-mounted device defined in claim 1 further comprising a strain gauge that is covered by the protective polymer.

4. The head-mounted device defined in claim 1 wherein the protective polymer comprises epoxy.

5. The head-mounted device defined in claim 4 wherein the epoxy comprises ultraviolet-light-cured thermoset epoxy and wherein the molded polymer frame portion comprises thermoplastic polymer.

6. The head-mounted device defined in claim 5 wherein the thermoplastic polymer comprises injection-molded thermoplastic polymer and wherein the molded polymer frame portion is configured to form a nose bridge portion.

7. The head-mounted device defined in claim 6 further comprising a strain gauge embedded in the protective polymer.

8. The head-mounted device defined in claim 7 wherein the strain gauge is configured to measure deformation of the internal frame.

9. The head-mounted device defined in claim 8 wherein the internal frame comprises a metal internal frame.

10. The head-mounted device defined in claim 9 wherein the metal internal frame has a C-shape.

11. The head-mounted device defined in claim 10 wherein the molded polymer frame portion is molded over at least part of the metal internal frame.

12. The head-mounted device defined in claim 5 wherein the thermoplastic polymer comprises a rear shot of thermoplastic polymer and a front shot of thermoplastic polymer.

13. The head-mounted device defined in claim 12 wherein the rear shot of thermoplastic polymer is configured to form a lens ledge.

14. The head-mounted device defined in claim 12 wherein the rear shot of polymer is configured to form lens mounting protrusions.

15. The head-mounted device defined in claim 12 wherein the internal frame comprises a metal internal frame with tabs, the head-mounted device further comprising projectors that are attached to the tabs.

16. The head-mounted device defined in claim 15 wherein the lenses comprise waveguides that guide images received from the projectors.

17. The head-mounted device defined in claim 16 wherein the cable is coupled to the projectors, the head-mounted device further comprising a strain gauge coupled to the cable, wherein the strain gauge is configured to measure deformation of the metal internal frame, and wherein the protective polymer encapsulates the strain gauge.

18. A head-mounted device, comprising:
a cable;
a sensor;
a head-mounted frame comprising:
a metal frame that supports the cable and the sensor,
thermoset polymer that is formed on at least part of the metal frame and that encapsulates at least part of the cable and the sensor, and
thermoplastic polymer that is formed over the thermoset polymer and the metal frame, wherein the thermoplastic polymer is configured to from lens openings; and
left and right lenses in the lens openings.

19. The head-mounted device defined in claim 18 wherein the thermoset polymer comprises epoxy.

20. A head-mounted device, comprising:
a metal frame;
projectors attached to opposing sides of the metal frame;
a strain gauge at a central region of the metal frame;
cabling coupled to the projectors and the strain gauge;
epoxy that covers the strain gauge;
thermoplastic polymer covering the epoxy and the metal frame, wherein the thermoplastic polymer is configured to form lens openings; and
lenses in the lens openings, wherein the lenses include waveguides configured to guide images from the projectors.
